(19) United States
(12) Patent Application Publication
(10) Pub. No.: US 2004/0091813 A1
(43) Pub. Date: May 13, 2004

(54) Fluorinated polymers

(75) Inventors: Andrew J. Poss, Kenmore, NY (US); Haridasan K. Nair, Williamsville, NY (US); David Nalewajek, West Seneca, NY (US); Michael Van Der Puy, Amherst, NY (US); Jing Ji Ma, West Seneca, NY (US)

Correspondence Address: SYNNESTVEDT & LECHNER, LLP, 2600 ARAMARK TOWER, 1101 MARKET STREET, PHILADELPHIA, PA, 191072950

(73) Assignee: Honeywell International Inc., Morristown, NJ

(21) Appl. No.: 10/697,347

(22) Filed: Oct. 30, 2003

Related U.S. Application Data
(60) Provisional application No. 60/423,886, filed on Nov. 5, 2002.

(51) Int. Cl. G03F 7/004

(52) U.S. Cl. 430/270.1; 430/286.1; 430/281.1; 430/322; 430/311; 430/315; 430/321; 430/320

(57) ABSTRACT

Provided are compounds described by the formula:

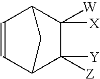

wherein W, X, Y, and Z are independently selected from the group consisting of hydrogen, fluorine, hydroxyl, substituted alkyl and unsubstituted alkyl. Also provided are methods of making compounds of the present invention, and polymers derived from one or more compounds of the present invention.

### CROSS-REFERENCE TO RELATED APPLICATION

This application claims the priority benefit of U.S. Provisional Application Serial No. 60/423,886, which was filed with the United States Patent and Trademark Office on Nov. 5, 2002 and is incorporated herein by reference.

### FIELD OF INVENTION

The present invention relates generally to polymers derived from fluorinated monomers and the uses of such polymers in lithographic imaging materials, especially photoresist compositions, as well as, dielectric, passivation and insulating materials, light guides, anti-reflective coatings and layers, pellicles, the production of semiconductor devices, and the like. The present invention also relates to novel monomer compounds used for making the polymers of the present invention, and to methods for making such monomer compounds.

### BACKGROUND OF THE INVENTION

Photoresists are organic polymeric materials which find use in a wide variety of applications, including lithographic imaging materials in superconductor applications. There is great interest in developing the next generation commercial 157 nm photoresists for a variety of applications in the semiconductor industry. See Chemical and Engineering News, page 23-24, Jul. 15, 2002.

One important property associated with effective photoresists is transparency of the photoresist to light at a given wavelength. Applicants have recognized that although many conventional polymers for optical lithography have demonstrated good performance for use as photoresists at a variety of wavelengths, such polymers nevertheless tend to lack transparency at 157 nm.

For example, U.S. Pat. No. 5,821,036, which is incorporated herein by reference, describes a method of developing positive photoresists and polymer compositions for use therein. While the disclosed polymer compositions are useful in the method of the '036 patent, such compositions tend to be non-transparent and unusable in 157 nm lithographic methods. U.S. Pat. No. 6,124,074, which is incorporated herein by reference, discloses acid catalyzed positive photoresist compositions which tend to be transparent to 193 mu light but not 157 nm light. U.S. Pat. No. 6,365,322, which is incorporated herein by reference, discloses photoresist compositions for deep UV region (100-300 nm) that tend to be non-transparent to 157 nm light.

Prior attempts have been made to produce fluorinated polymers that are substantially transparent to light at wavelengths lower than those described in the '036, '074, and '322 patents. See, for example, PCT WO 00/67072 and Tran et al Macromolecules 2002, 35, 6539-6549 (describing certain fluorinated norbornene-based polymers), each of which is incorporated herein by reference. Although these polymers may show promise for transparency at 157 nm, applicants have recognized the need for polymers which are not only transparent at 157 nm, but also exhibit resistance to plasma, adhesion to a wide range of substances/surfaces, and exceptional mechanical properties in 157 nm lithography applications. Accordingly, the present invention describes the preparation of novel fluorinated monomers for making polymers for 157 nm photoresists.

### DESCRIPTION OF THE INVENTION AND PREFERRED EMBODIMENTS

The present invention provides novel norbornene-based monomers and fluorinated polymers derived therefrom that can be used to great advantage in a number of applications including, for example, in lithographic imaging materials, especially photoresist compositions, as well as, dielectric, passivation and insulating materials, light guides, anti-reflective coatings and layers, pellicles and glues. The polymers of the present invention provide transparency and low optical loss in key areas of the ultraviolet (“UV”) and infrared (“IR”) spectrum, are sensitive to actinic radiation, and are resistant to the reactive environment associated with ion etching. Accordingly, such polymers are particularly suited for use in photoresist applications, as well as other light-sensitive applications.

### Monomers

According to certain embodiments, the present invention provides monomer compounds described by Formula I, below:

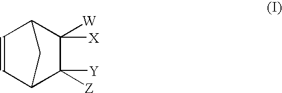

wherein W, X, Y, and Z are independently selected from the group consisting of hydrogen, fluorine, hydroxyl, substituted and unsubstituted alkyl, substituted and unsubstituted fluoroalkyl, provided that: (i) at least one of W, X, Y, and Z is fluorine or a group comprising fluorine, (ii) W, X, Y, and Z are not all the same moiety, (iii) when W and X are both hydrogen, Y and Z are not both hydroxyl, both fluorine, or both alkyl, (iv) when W and Z are both hydrogen or both fluorine, X and Y are not both hydroxyl, (v) when W, X, and Y are all hydrogen, Z is neither methyl nor hydroxyl, (vi) when X and Y are both H, and W is CH₂OH, Z is not C₃F₇ or CF₃; and (vii) when W is hydrogen and X is hydroxyl, Y and Z are not both fluorine.

W, X, Y, and Z as independently selected alkyl groups may be straight-chain or branched molecules. Examples of suitable alkyl groups include alkyls having from about 1 to about 15 carbon atoms, such as, methyl, ethyl, n-propyl, isopropyl, n-butyl, isobutyl, tert-butyl, n-pentyl, neopentyl, hexyls, heptyls, octyls, nonyls, decyls, undecyls, dodecyls, and the like. Any of these groups may be unsubstituted, or may be further substituted with halogen, hydroxyl, alkoxy, aryloxy, alkyl, fluoroalkyl, arylalkyl groups, and the like. In a preferred class of alkyls, W, X, Y, and/or Z is a fluorinated alkyl, a hydroxy-substituted alkyl, or a hydroxy-substituted fluorinated alkyl, including, for example, trifluoromethyl, —C(CF₃)₂0H, and compounds of the formula -(A)n-R, wherein A is CH₂ or CF₂, n is from about 0 to about 15, and R is hydrogen, fluorine, trifluoromethyl, hydroxyl or —C(CF₃)₂OH.

In certain preferred embodiments, the compounds of Formula I comprise two or more W, X, Y, and Z groups that are the same moiety. Examples of such preferred compounds include compounds of Formula I wherein W and Z are both hydrogen, both fluorine, or both trifluoromethyl, and compounds wherein W, Y, and Z are all hydrogen, all fluorine, or all trifluoromethyl. Other examples of such preferred compounds include those described by Formulae Ia and Ib, below:

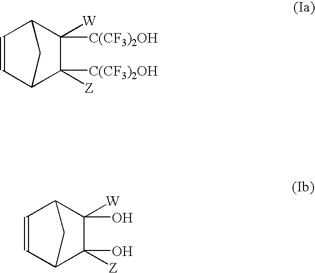

Certain preferred compounds described by Formulae Ia include compounds wherein W and Z are the same moiety. For example, preferred compounds of Formula Ia include compounds wherein W and Z are both hydrogen or both trifluoromethyl. Certain preferred compounds of Formula Ib include compounds wherein W and Z are both independently substituted or unsubstituted fluoroalkyls. Certain preferred compound of Formula Ib include compounds wherein W and Z are both the same substituted fluoroalkyl, such as trifluoromethyl.

According to certain other embodiments, preferred compounds of Formula I comprise compounds described by the formula Ic, below:

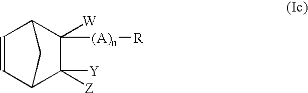

wherein W, Y, and Z are independently hydrogen, fluorine, trifluoromethyl, or —C(CF₃)₂OH, and A, n, and R are defined as above. In certain preferred compounds of formula Ic, W and Z are both hydrogen, both fluorine, or both trifluoromethyl, or W, Y, and Z are all hydrogen, all fluorine, or all trifluoromethyl. Certain other preferred compounds of formula Ib include compounds wherein R is hydroxyl.

Other preferred compounds of Formula I are described by Formula Id, below:

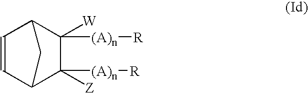

wherein W and Z are independently hydrogen, fluorine, or trifluoromethyl, and A, n, and R are as defined above. The two -(A)n-R groups in compounds of Formula Id can be the same or different. In certain preferred embodiments, the two -(A)n-R groups are both -(A)n-C(CF₃)₂OH groups. In certain other preferred embodiments, W and Z are both hydrogen, both fluorine, or both trifluoromethyl. In certain highly preferred embodiments, the two -(A)n-R groups are both -(A)n-C(CF₃)₂OH groups, and W and Z are both hydrogen, both fluorine, or both trifluoromethyl.

The monomer compounds of the present invention can be prepared via a number of methods according to the present invention. For example, the present invention provides for the preparation of certain preferred compounds of Formula I from norbornene starting materials via the reaction schemes (Schemes 1-3) shown below:

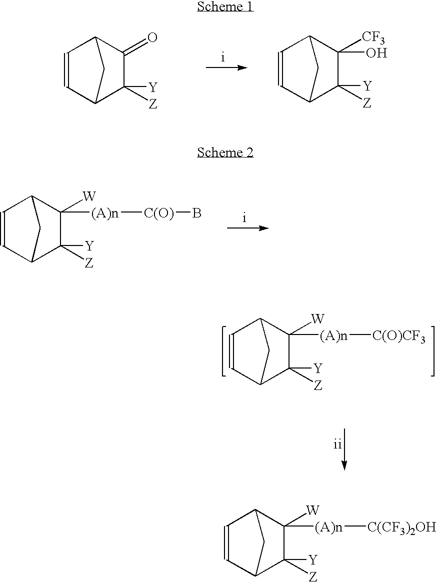

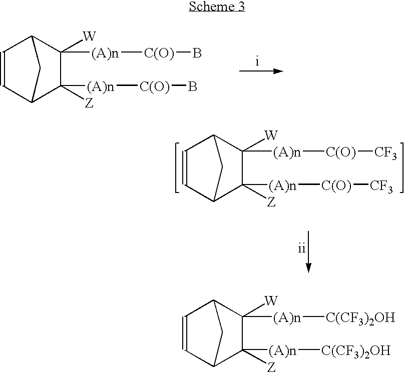

wherein B is a leaving group, including, for example, nitrile, alkoxy, aryloxy, halogen, and the like.

Step i in schemes 1-3 comprises generally reacting a suitable starting material, preferably a suitable norbornene ketone, ester, acyl halide, or mixture of two or more thereof, and the like, with trifluoromethyltrimethyl silane (CF₃TMS) in the presence of a catalytic amount of fluoride to produce an alcohol (Scheme 1) or a ketone (Schemes 2 and 3). Any of a wide range of ketones, esters, and acyl halides are suitable for use as starting materials in the present methods. Examples of suitable ketones, esters, and acyl halides are disclosed, for example, in McBee, E. T.; J. Am. Chem. Soc. 38, 632, 1956, which is incorporated herein by reference. A number of such starting materials are available commercially and/or can be prepared by those of skill in the art via art recognized procedures.

Trifluoromethyltrimethyl silane is available from a number of commercial sources, including, for example, from Aldrich Chemical Co. Any commercially available or other suitable trifluoromethyltrimethyl silane may be used according to the methods of the present invention.

Any of a wide variety of suitable fluoride ion source materials may be used according to the present invention. Examples of suitable fluoride ion sources include tetraalkyammonium fluorides (R₄N⁺F⁻; R=alkyl), such as tetrabutyl ammonium fluoride (TBAF) and the like, as well as metal fluorides, including, cesium fluoride, potassium fluoride, and the like, and combinations of two or more thereof. A number of such fluoride sources are available commercially, for example, TBAF and cesium fluoride are available from Aldrich.

Any suitable solvent can be used in the present invention. Examples of suitable solvents include hexane, pentane, THF, and the like.

Any suitable amounts of reagents and reaction conditions can be used in step i of the present methods. The particular amounts and reaction conditions used in any given reaction will depend on the particular reactants and catalyst used. Examples of suitable reaction conditions that can be adapted for use herein are disclosed in J. Org. Chem 64, 2873-2876 (1999) incorporated herein by reference.

Step ii in schemes 2 and 3 comprises generally reacting a ketone formed in step i with CF₃TMS in the presence of a catalytic amount of fluoride ion to form a silyl ester, and subsequently desilylating the ester to form the target alcohol compound. Any suitable fluoride ion, CF₃TMS and reaction conditions as described above can be used to form the silyl ester according to the present invention. Furthermore, the silyl ester may be desilylated using any of a wide range of known methods. For example, desilylation can be carried out via the addition of excess fluoride ion, water, ether, combinations of two or more thereof, and the like. Suitable conditions for desilyating the silyl esters of the present method are described in, for example, Synlett. 1306 (2000) and J. March, Advanced Organic Chemistry, (Fourth Ed. 1992), both of which are incorporated herein by reference.

The present invention also provides for the preparation of compounds of Formula I from alkene starting materials. For example, reaction schemes 4 and 5, shown below, illustrate methods of making compounds of Formula I from alkenes according to certain preferred embodiments of the present invention.

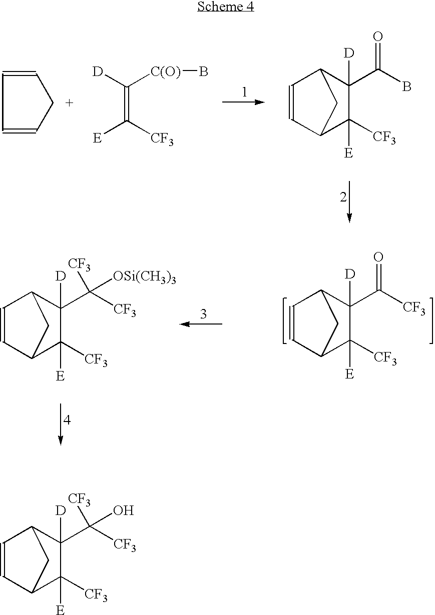

wherein D and E are independently hydrogen, halogen, alkyl (especially fluorinated alkyl), and the like.

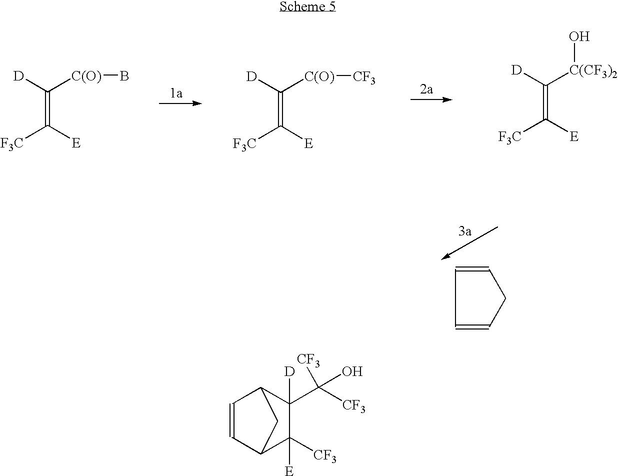

Step 1 in Scheme 4 and step 3a in Scheme 5 are Diels-Alder reactions. Any of a wide variety of conventional Diels-Alder reaction procedures and conditions can be adapted for use herein. The particular set of reaction conditions used in any given reaction will depend on the particular reactants and catalyst used and the time and yield of product desired. Examples of suitable reaction conditions that can be adapted for use herein are disclosed in J. March, Advanced Organic Chemistry, pages 839-856 (Fourth Ed. 1992) and U.S. Pat. No. 6,468,712, both of which are incorporated herein by reference.

Step 2 in Scheme 4 and step 1a in Scheme 5 comprise reacting an acyl halide, ester, or ketone with CF₃TMS in the presence of a catalytic amount of fluoride ion to form a ketone. Any suitable reagents and conditions as described above for Schemes 1-3 can be used.

Steps 3 and 4 in Scheme 4 and step 2a in Scheme 5 comprise reacting a ketone with CF₃TMS in the presence of a catalytic amount of fluoride ion to form a silyl ester, and subsequently desilylating the ester to form a target compound. Any suitable fluoride ion, CF₃TMS and reaction conditions as described above can be used to form the silyl ester according to the present invention. Furthermore, the silyl ester may be desilylated using any of the methods described above.

### Polymers

The monomer compounds of the present invention can be incorporated advantageously into polymers suitable for use in a wide variety of applications. Accordingly, in certain embodiments, the present invention provides polymers comprising one or more repeating units derived from at least one monomer compound of the present invention. Preferably, the polymers of the present invention comprise at least one repeating unit described by Formula II, below:

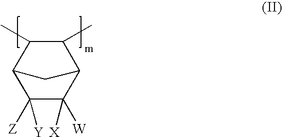

wherein W, X, Y, and Z are as defined above for compounds of Formula I. In certain other preferred embodiments, the polymers of the present invention comprise at least one repeating unit described by Formula IIa, below:

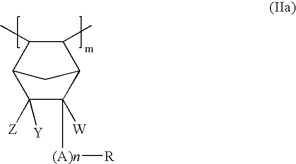

wherein A, n and R are as defined above.

The polymers of the present invention may be homopolymers comprising repeating units derived from only one compound of the present invention or polymers comprising repeating units derived from a plurality of compounds of the instant invention. Polymers of the present invention comprising repeating units derived from two or more monomer compositions of the present invention may be copolymers, block copolymers, terpolymers, polymers comprising four or more different types of repeating units, combinations of two or more thereof, and the like.

In certain other embodiments, the polymer of the present invention may include one or more repeating units derived from other monomers, oligomers, or polymer compounds that have been copolymerized with at least one compound described by Formula I of the present invention. Suitable other monomers, oligomers, and polymer compounds include, for example, norbornene monomers, such as bicyclo[2.2.1]hept-5-ene-2-( 1,1,1-trifluoro-2-trifluoromethylpropan-2-ol) (NBHFA), ethylenically unsaturated compounds, especially those containing at least one fluorine substituent, and the like. Preferred ethylenically unsaturated compounds include those defined by the formulae: CF₂═CF₂, CF₂═CH₂, CF₂═CFCl, CF₂═CHF, CF₃CH═CF₂; CF₃CH═CHF; CF₃CF═CHF; CF₃CF═CH₂; and Rf(CH₂)ₚCX_{f}═C_{f}Y_{f} wherein p is from 0 to about 20; Rf is a perfluoroalkyl group having from about 1 to about 10 carbon atoms, X_{f} and Y_{f} are independently H or F, provided that when Rf is CF₃ and X_{f} is F, Y_{f} must be H, and the like.

The polymers of the present invention are prepared by polymerizing one or more compounds described by Formula I, optionally in the presence of any additional monomer compounds to be copolymerized therewith. Any of a wide range of known methods for polymerizing the present compounds can be used according to the present invention. For example, the monomer compounds may be polymerized via exposure to light or heat and/or through the use of a catalyst. In certain embodiments, the polymers of the present invention are prepared by polymerizing a reaction mixture containing the monomer compounds to be polymerized and a single or multicomponent metal catalyst system as disclosed in the published patent application WO 97/33198 (assigned to B.F. Goodrich and incorporated herein by reference.) The polymers of the present invention can also be prepared, for example, using nickel or palladium catalysts as disclosed in Risse, Makromol Chem., Rapid Commun., vol. 12, pages 255-259 (1991), Hung, Proceedings of SPIE, vol. 4345, pages 385-395 (2001), and U.S. Pat. No. 6,468,712, all of which are incorporated herein by reference. In light of the disclosure herein and the cited documents, those of skill in the art will be readily able to produce polymers of the present invention without undue experimentation.

The polymers of the present invention have utility in a wide range of applications. For example, one embodiment of the present invention relates to the use of the present polymers in photoresist compositions. The polymers of the present invention preferably exhibit beneficial transparency characteristics for a range of UV irradiation, most notably at about 157 nanometers, and/or other characteristics that make them particularly suitable for use in photoresist applications.

In certain embodiments, the photoresist compositions of the present invention comprise a polymer of the present invention. In certain other embodiments, the photoresists of the present invention further comprise a solvent and a photoinitiator (for example, a photosensitive acid generator). Any of a wide range of solvents are suitable for use in the photoresist compositions of the present invention. For example, any of the solvents disclosed in published patent application WO 97/33198 may be used herein. In certain embodiments, the solvent for use in the present invention is carbon dioxide. In certain preferred embodiments, the carbon dioxide solvent is in its supercritical state.

Any of a wide range of photoinitiators are suitable for use in the present photoresist compositions. Examples of suitable photoinitiators include those disclosed in published patent application WO 97/33198. In certain embodiments, the photoinitiator is preferably present in an amount of from about 1 to about 100 w/w % to polymer. More preferably, the photoinitiator is present in an amount of about 5 to about 50 w/w %.

In certain embodiments, the photoresist compositions of the present invention further comprise a dissolution inhibitor. Any of a wide range of known dissolution inhibitors can be used in the practice of the present invention. For example, t-butyl cholate and the like may be used as a dissolution inhibitors in the present photoresist compositions. Any suitable amount of dissolution inhibitor can be used. Preferably, the dissolution inhibitor is used in an amount of up to about 20 weight % of the photoresist composition.

In certain embodiments, the photoresist compositions of the present invention further comprise a sensitizer capable of sensitizing the photoinitiator to longer wavelengths ranging from mid-UV to visible light. Examples of suitable sensitizers are disclosed in WO 97/33198, and U.S. Pat. Nos. 4,250,053; 4,371,605; and 4,491,628, all of which are incorporated herein by reference.

The photoresist compositions of the present invention can be used to generate a positive tone resist image on a substrate. The present invention provides a method for generating a positive tone resist image on a substrate comprising the steps of (a) coating a substrate with a film comprising a photoresist composition of the present invention, (b) imagewise exposing the film to radiation, and (c) developing the image. The coating, radiating and developing steps can be performed using known techniques. For example, the procedures described in application WO 97/33198 can be adapted for use in the present invention. In light of the disclosure contained herein, those of skill in the art would be readily able to generate a positive resist image according to the methods of the present invention.

The present invention also relates to an integrated circuit assembly, such as an integrated circuit chip, multichip module, or circuit board made by the process and/or using the polymers of the present invention. The integrated circuit assembly preferably comprises a circuit formed on a substrate by the steps of (a) coating a substrate with a film comprising a photoresist composition of the present invention, (b) exposing the film to radiation, (c) developing the image to expose the substrate, and (d) forming the circuit or pattern on the substrate. Any of a wide range of known techniques, including those described in application WO 97/33198, can be adapted for use in the methods of the present invention.

The present polymers also find use as dielectric, passivation and insulating materials, optical wave/light guides, anti-reflective coatings and layers, pellicles and the like.

### EXAMPLES

In order that the invention may be more readily understood, reference is made to the following examples which are intended to be illustrative of the invention, but are not intended to be limiting in scope.

### Example 1

This Example illustrates the preparation of a compound of the formula:

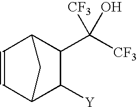

from Y—CH═CH—C(O)ORₐₗₖ, wherein Y is as described above and Rₐₗₖ is a C₁-C₈ alkyl group.

Cyclopentadiene is reacted under Diels-Alder conditions with Y—CH═CH—C(O)ORₐₗₖ to form compound E1a, below.

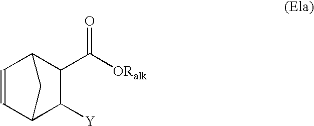

Compound E1a is then treated with 1.1 equivalent of trifluoromethyltrimethylsilane (CF₃TMS) in the presence of tetrabutylammonium fluoride (TBAF) at from about −70° C. to about 30° C. The resulting mixture is warmed to about 25-30° C. to form a ketone intermediate E1b, below.

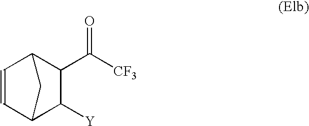

Intermediate E1b is not isolated but is used for the next step.

Ketone intermediate E1b is treated with additional amount, 1.2 equivalents, of CF₃TMS at −40° C. and warmed to 10° C. in the presence of catalytic amount of fluoride ion source (TBAF) to form compound E1c, below.

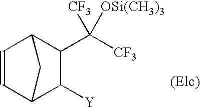

Compound E1c is then converted to the target alcohol by treating with excess (1.5 to 2 equivalents) TBAF in tetrahydrofuran (THF) or by heating with a solution of a base, such as sodium hydroxide.

Each step of the reaction is monitored by gas chromatography (GC) analysis. Isolation and purification employs conventional methods such as extraction, filtration, distillation, and chromatography. The structure of the compounds is confirmed by conventional methods such as NMR and MS analyses.

### Example 2

This example illustrates the preparation of 1,1,1,3,3,3-hexafluoro-2-[3-(trifluoromethyl)bicyclo[2,2,1]hept-5en-2-yl]propan-2-ol.

To a solution of ethyl 3-(trifluoromethyl)bicyclo[2.2.1]hept-5ene-2-carboxylate (23.1 g, 0.098 mol), anhydrous pentane (100 mL) and trifluoromethyltrimethylsilane, CF₃TMS, (18 g, 0.126 mol) under nitrogen purge at −60° C. was added 3 mL 1.0 M tetrabutyl ammonium fluoride (TBAF) (3 mmol) in THF (dried over molecular sieves) drop-wise with stirring. The reaction mixture was slowly warmed to −20° C. with stirring. A dark solution concomitant with gaseous evolution resulted. The solution was stirred at −0-5° C. for 30 minutes and analyzed by GC which indicated the formation of a ketone as the main product with some unreacted starting material (<5%).

The above reaction mixture was cooled to −40° C., and additional CF₃TMS (17 g, mmol) followed by 3 mL 1.0 M TBAF was added with stirring. The solution was gradually brought to room temperature (20° C.) with stirring. After stirring for an hour, a dark brown solution resulted. GC analysis indicated a silyl ether as the major compound. The resultant dark brown solution was concentrated under reduced pressure (390-80 mm Hg) on rotary evaporator at 25-30° C. The brown residue thus obtained was taken in 250 mL ether, and washed with water (2×50 mL). The ether layer was separated, concentrated (520 to 75 mm Hg) to afford 33 g which was flash chromatographed (hexanes, then hexanes+methanol, 95/5 v/v) and distilled (50-59° C./9 mm Hg) to afford 13 g 1,1,1,3,3,3-hexafluoro-2-[3-(trifluoromethyl)bicyclo[2,2,1]hept-5en-2-yl]propan-2-ol (yield=40% based on starting material carboxylate). Further purification is achieved by chromatography. The NMR and MS spectral data are consistent with the structure.

EI/MS: m/e 328 for M⁺ (M=C₁₁H₉F₉O); ¹⁹F NMR (CDCl₃) δ=−64.3 (m, 3F), −72.4 (q, 3F), −75.5 (m, 3F) (For the other isomer, −64.7 (3F), −73.6 (q, 3F)), −76.1(m, 3F).(isomers in the ratio; 95:5 ); ¹H NMR (CDCl₃) δ=6.34 (dd, 1H), 6.17 (m, 1H), 3.24-3.13 (overlaps, m, 4H), 2.18 (m, 1H), 1.68 (m, 1H), 1.51 (d, 1H) ppm.

### Example 3

This example illustrates the preparation of 1,1,1,3,3,3-hexafluoro-2-[3-(trifluoromethyl)bicyclo[2,2,1]hept-5en-2-yl]propan-2-ol.

To a one-liter, round-bottom flask equipped with temperature probe, mechanical stirrer, and a water condenser is added ethyl 3-(trifluoromethyl)bicyclo[2.2.1]hept-5ene-2-carboxylate (115 g, 0.49 mol), anhydrous pentane (500 mL), and trifluoromethyltrimethylsilane, CF₃TMS, (90 mL, 0.63 mol) under a nitrogen blanket. The stirred reaction mixture is cooled to 11° C. and 15 mL of 1.0 M tetrabutyl ammonium fluoride (TBAF) (0.015 mol) in THF (dried over molecular sieves overnight ˜1 g mol sieve/4 ml soln) is added drop-wise over a period of 30 minutes. (Note: The addition of TBAF must be slow; the reaction is exothermic.) The reaction mixture becomes light yellow, and then a dark solution concomitant with gaseous evolution results. The reaction mixture is stirred at this temperture for 1 hour and gradually warmed to ˜22° C. and analyzed by GC which indicates the desired ketone as the main product with some unreacted starting material (<5%). (This reaction mixture can be left overnight at RT under N₂ blanket.) The reaction mixture is concentrated on a rotavap from about 430 mm Hg to 130 mm Hg at ˜45 ° C. to afford 158 g of a brown liquid to which 400 ml diethyl ether is added, washed with 2×250 ml de-ionized water, dried using MgSO₄, filtered, and concentrated under 100 mm Hg at 30° C. to afford 146.5 g crude ketone which is used in the next step.

In a second step, to a mixture of 146. 5 grams crude ketone from step 1, anhydrous pentane (400 ml) and 90 mL CF₃TMS, is added 15 mL of 1.0 M TBAF in THF dropwise at 13° C. (Note: Exothermic reaction!). The reaction mixture is brought to room temperature and an exotherm is observed with rapid gaseous evolution (temperature rising to 36° C.; temperature is moderated by a water bath). The reaction mixture is stirred for 2 hours, concentrated under ˜430 to 10 mm Hg at 37° C. The resultant residue is taken in 500 mL ether, washed with de-ionized water (2×250 mL), dried using MgSO₄, and concentrated to remove ether and to afford 125.2 g crude product. The product was distilled (32-27° C./1 mm Hg) to afford 86 g of material.

The 86 g of crude product is taken in 250 ml hexanes and extracted using 2×65 mL 4N NaOH. The aqueous layer is neutralized with HCl and extracted with 250 ml hexanes, dried using MgSO₄, and removed using hexanes to afford the pure product (80 g).

The NMR and MS spectral data are consistent with the structure.

### Example 4

This example illustrates the preparation of 2-bicyclo[2.2.1]hept-5-en-2-yl-1,1,1,3,3,3-hexafluoropropan-2-ol.

By the same procedure as described in Example 2, ethyl bicyclo[2.2.1]hept-5-ene-2-carboxlyate is reacted with CF₃TMS in the presence of TBAF to form 2-bicyclo[2.2.1]hept-5-en-2-yl-1,1,1,3,3,3-hexafluoropropan-2-ol in a yield of about 55% based on the starting carboxylate. Spectral data are consistent with the structure.

### Example 5

This example illustrates the polymerization of a monomer compound according to certain embodiments of the present invention.

To 100 mL round bottom flask equipped with a stir bar and kept in a dry box are added, allylpalladium chloride dimer (3.7 mmol) and silver hexafluorantimonate (7.3 mmol). After addition of 50 mL dry dichloromethane, the mixture is stirred at room temperature for 20 minutes. The reaction mixture is filtered via 0.45 mm syringe filter to a 100 mL flask containing a compound of Formula I (73 mmol) in 50 mL dichlormethane. The reaction mixture is stirred at room temperature for 24 hours, then precipitated into hexanes ( 2 L). The resulting light cream colored powder is collected via filtration and dried to afford a homopolymer of the present invention. Further purification is done by treatment with activated carbon, filtration and drying.

### Example 6

This example illustrates the polymerization of a monomer compound according to certain other embodiments of the present invention.

To a 50 mL glass vial equipped with a Teflon coated stir bar is added a monomer compound of Formula I. The monomer compound is stirred at ambient temperature and a catalyst solution is added thereto. (The catalyst solution is prepared by adding η³-allylpalladium chloride dimer (38 mg, 0.1 mmol) in 5 mL chlorobenzene to silver hexafluoroantimonate (99 mg, 0.3 mmol) in 5 mL chlorobenzene for 30 minutes and then filtering through a micropore filter to remove precipitated silver chloride). The reaction is allowed to run for 36 hours. After this time, the mixture gels to form a clear yellow gel. Upon adding the gel to excess methanol, the polymer precipitates as a white powder. The polymer is washed with excess methanol and dried.

### Example 7

This example illustrates the preparation of 3,3 -bis(trifluoromethyl)bicyclo [2.2.1]hept-5 -en-2-yl]methan-1-ol.

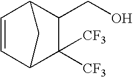

To a 250 mL round-bottom flask is added 1.8 g lithium aluminum hydride (LAH) (1.8 g, 48 mmol) under nitrogen atmosphere. The flask is cooled to ˜5° C. and 50 mL anhydrous ether is added. The LAH in ether is stirred for 5 minutes at this temperature and ethyl 3,3-bis(trifluormethyl)bicyclo[2.2.1]hept-5-ene-2-carboxylate (10.7 g, 35.4 mmol) in 15 mL dry ether is added dropwise in such a way that the temperature does not rise >8° C. (Caution! Exothermic). After complete addition, the reaction mixture is stirred at ˜5° C. for 1 hour. Then the reaction mixture is cooled to ˜0° C. and quenched by slow addition of water (6 mL) followed by 6 mL 20% solution of sodium hydroxide. Ether (50 mL) and 6 mL water is added to the stirred reaction mixture and brought to room temperature. The ether layer is separated and aq. layer is extracted with 2×20 mL ether. The combined ether layer is washed with brine 10 ml, dried using MgSO₄, and concentrated under reduced pressure. Removal of the solvent at 2 mm Hg and 35° C. affords product as a white powder (7.25 g, yield 79%), mp 64-66° C. Spectral data are consistent with the structure.

GC/MS: m/e 260 for M⁺ for C₁₀H₁₀F₆O; ¹⁹F NMR (CDCl₃) δ−61.2 (q, 3F, J=14 Hz) and −62.3 (q, 3F, J=13 Hz) ppm for isomer 1; −57.4(3F, q, J=12 Hz), −67.2(3F, q, J=12 Hz) ppm for isomer 2; the ratio of isomers is 3:1. ¹H spectrum is consistent with the structure.

### Example 8

### Step 1

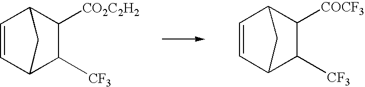

Under nitrogen, ethyl 3 -(trifluoromethyl)bicyclo(2,2,1)hepta-5-ene-2-carboxylate (100 g, 0.428 mol), trifluoromethyl trimethyl silane (80 mL, 75 g, 0.53 mol) and pentane (320 mL) were added into a 1 L three-neck jacketed flask equipped with a stirrer, thermometer and addition funnel. The reaction mixture was cooled to about 15° C. and 1M tetrabutylammonium fluoride (TBAF) solution in THF (14 mL, dried over 4 A molecular sieves) was added dropwise with stirring. The TBAF/THF solution was added in such a way that the temperature of the reaction mixture was substantially maintained at ˜20-25° C. After complete addition, the reaction mixture was stirred at room temperature overnight (˜15 h), concentrated on a rotary evaporator (40° C./130 mmHg) to afford 140 g of a brown liquid. Magnesium sulfate (MgSO₄) (˜25 g) was added to the brown liquid, filtered and crude ketone was directly used for next step of the reaction. [Note: At <15° C., silyl ether was formed as main product instead of the ketone].

### Step 2

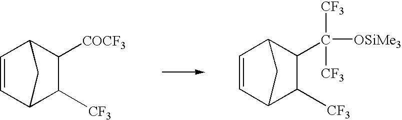

The ketone (140 g) from step 1 and pentane (320 mL) were added into a 1 L three necked jacketed flask equipped with a stirrer, thermometer, addition funnel and N₂ inlet. The jacket temperature was maintained at 15° C. Trifluoromethyl trimethyl silane (CF₃TMS) (80 mL, 79 g) was added dropwise into the stirred reaction mixture such a way that the temperature of the reaction mixture was ˜18-25° C. After complete addition, the jacket temperature was raised and maintained at 40° C. for 2 h. The resultant dark brown reaction mixture was concentrated on a rotory evaporator and distilled at reduced pressure (1 mm Hg) at 65-70° C. to afford 135 g yellow liquid which was 90% silyl ether.

### Step 3

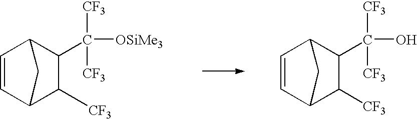

The distilled silyl ether (135 g) from step 2 was stirred with 250 mL 4N NaOH till no silyl ether waspresent as indicated by GC (0.5 mL reaction mixture was acidified (pH˜6) with HCl and extracted with ether and analyzed by GC). The aqueous solution was washed with 2×50 mL hexane, acidified with concentrated HCl (pH˜6), the organic phase formed was separated and extracted with 2×100 mL ether. The extracts were combined and dried with MgSO₄ (˜100 g), filtered, and concentrated on a rotary evaporator. The crude alcohol thus obtained was fractionally distilled to afford 92g (average yield from two batch preparations, Yield=64% ), b.p. 35-40° C./1 mmHg, GC purity>99%.

Spectral (NMR and MS) data were the same as given in Example 2.

What is claimed is:

1. A compound according to the formula: 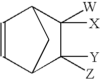
wherein W, X, Y, and Z are independently selected from the group consisting of hydrogen, fluorine, hydroxyl, substituted and unsubstituted alkyl, substituted and unsubstituted fluoroalkyl, provided that: (i) at least one of W, X, Y, and Z is fluorine or a group comprising fluorine, (ii) W, X, Y, and Z are not all the same moiety, (iii) when W and X are both hydrogen, Y and Z are not both hydroxyl, both fluorine, or both alkyl, (iv) when W and Z are both hydrogen or both fluorine, X and Y are not both hydroxyl, (v) when W, X, and Y are all hydrogen, Z is neither alkyl nor hydroxyl, (vi) when X and Y are both H, and W is CH₂OH, Z is not C₃F₇ or CF₃; and (vii) when W is hydrogen and X is hydroxyl, Y and Z are not both fluorine.

2. A compound of claim 1 selected from the group consisting of compounds described by the formulae (a)-(c) below: 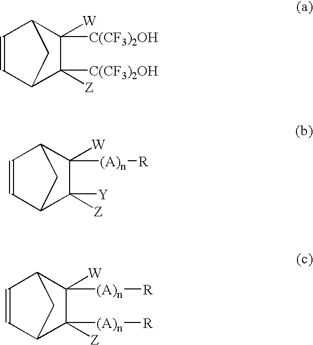
wherein W, X, Y, and Z are independently selected from the group consisting of hydrogen, fluorine, hydroxyl, substituted and unsubstituted alkyl, substituted and unsubstituted fluoroalkyl; each A is independently CH₂ or CF₂; each n is independently from about 0 to about 15; and each R is independently hydrogen, fluorine, trifluoromethyl, hydroxyl, or —C(CF₃)₂OH.

3. The compound of claim 2 wherein said compound is described by the formula: 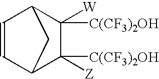
wherein W and Z are independently hydrogen or trifluoromethyl.

4. The compound of claim 3 wherein W and Z are the same moiety.

5. The compound of claim 2 wherein said compound is described by the formula: 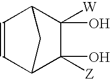
wherein W and Z are independently substituted or unsubstituted fluoroalkyl.

6. The compound of claim 5 wherein W and Z are the same moiety.

7. The compound of claim 2 wherein said compound is further described by the formula: 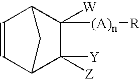
wherein:
W, Y, and Z are independently hydrogen, fluorine, trifluoromethyl, or —C(CF₃)₂OH; each A is independently CH₂ or CF₂; each n is independently from about 0 to about 15; and R is hydrogen, fluorine, trifluoromethyl, hydroxyl, or —C(CF₃)₂OH.

8. The compound of claim 7 wherein R is —C(CF₃)₂OH.

9. The compound of claim 8 wherein n=0, and Y and Z are trifluoromethyl.

10. The compound of claim 7 wherein W and Z are the same moiety selected from the group consisting of hydrogen, fluorine, and trifluoromethyl.

11. The compound of claim 7 wherein W, Y, and Z are all the same moiety selected from the group consisting of hydrogen, fluorine, and trifluoromethyl.

12. The compound of claim 2 wherein said compound is further described by the formula: 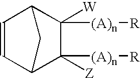
wherein:
W and Z are independently hydrogen, fluorine, trifluoromethyl, or —C(CF₃)₂OH; each A is independently CH₂ or CF₂; each n is independently from about 1 to about 15; and each R is independently hydrogen, fluorine, trifluoromethyl, hydroxyl, or —C(CF₃)₂OH.

13. The compound of claim 12 wherein W and Z are the same moiety selected from the group consisting of hydrogen, fluorine, and trifluoromethyl.

14. The compound of claim 12 wherein the two -(A)n-R groups are both -(A)n-C(CF₃)₂OH groups.

15. A polymer comprising at least one repeating unit derived from a monomer compound according to claim 1.

16. The polymer according to claim 15, further comprising one or more repeating units derived from a compound selected from the group consisting of bicyclo[2.2.1]hept-5-ene-2-(1,1,1-trifluoro-2-trifluoromethylpropan-2-ol) (NBHFA), CF₂═CF₂, CF₂═CH₂, CF₂═CFCl, CF₂═CHF, CF₃CH═CF₂, CF₃CH═CHF, CF₃CF═CHF, CF₃CF═CH₂, compounds of the formula R_{f}CH₂)ₙCXf=CXfYf wherein Rf is a perfluoroalkyl group having from about 1 to about 10 carbon atoms, Xf and Yf are indepedently H or F, provided that when Rf is CF₃ and Xf is F, Yf must be H, and mixtures of two or more thereof.

17. A photoresist composition comprising a polymer according to claim 15.

18. A photoresist composition comprising a polymer according to claim 16.

19. The photoresist composition of claim 18 further comprising a solvent and a photoinitiator.

20. The photoresist composition of claim 19 further comprising a dissolution inhibitor.

21. The photoresist composition of claim 20 further comprising a sensitizer.

22. A method for generating a positive tone resist image on a substrate comprising the steps of coating a substrate with a film comprising a photoresist composition of claim 17, exposing the film to radiation, and developing the image.

23. An integrated circuit assembly comprising a circuit formed by the steps of coating a substrate with a film comprising a photoresist composition of claim 17, exposing the film to radiation, developing the image to expose the substrate, and forming a circuit on the substrate.

24. An optical wave guide comprising a polymer according to claim 15.

25. An anti-reflective coating comprising a polymer according to claim 15.

26. A pellicle comprising a polymer according to claim 15.
